(19) United States
(12) Patent Application Publication
(10) Pub. No.: US 2026/0324047 A1
(43) Pub. Date: Oct. 15, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wei Ting WANG, Hsinchu (TW); Yi-Ruei JHAN, Hsinchu (TW); Kuan-Ting PAN, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 19/176,777

(22) Filed: Apr. 11, 2025

(51) Int. Cl. H10D 84/01; H10D 64/01; H10D 84/83

(52) U.S. Cl. CPC H10D 84/0153; H10D 64/017; H10D 84/833

(57) ABSTRACT

A semiconductor device includes a first channel region, a second channel region, and a dielectric structure. The first channel region extends over a semiconductor substrate. The second channel region extends over the semiconductor substrate and is parallel to the first channel region in a first direction. The dielectric structure is disposed between the first and second channel regions, wherein the dielectric structure comprises a dielectric wall and a liner, the dielectric wall has a first surface facing the first channel region, a second surface facing the second channel region, a third surface connecting the first and second surfaces, and a fourth surface opposing the third surface. The liner is disposed over middle portions of the third and fourth surfaces of the dielectric wall.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 11A, 11B, 11C, 12A, 12B, 12C, 12D, 13, 14, 15, 16, 17, 18, 19, 20A, 20B, 21A and 21B are cross-sectional views of intermediate stages in the manufacturing of nano-FETs, in accordance with some embodiments.

FIG. 22 illustrates an example of a nanostructure field-effect transistor (nano-FET) in a cross-sectional view, in accordance with some embodiments.

FIGS. 23A to 23C illustrate an example of intermediate stages in the manufacturing of nano-FET, respectively.

FIGS. 24A to 24B illustrate an example of top views of intermediate stages in the manufacturing of nano-FET, respectively.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments discussed herein are described in the context of a die including nano-FETs. However, various embodiments may be applied to dies including other types of transistors (e.g., fin field effect transistors (FinFETs), planar transistors, or the like) in lieu of or in combination with the nano-FETs.

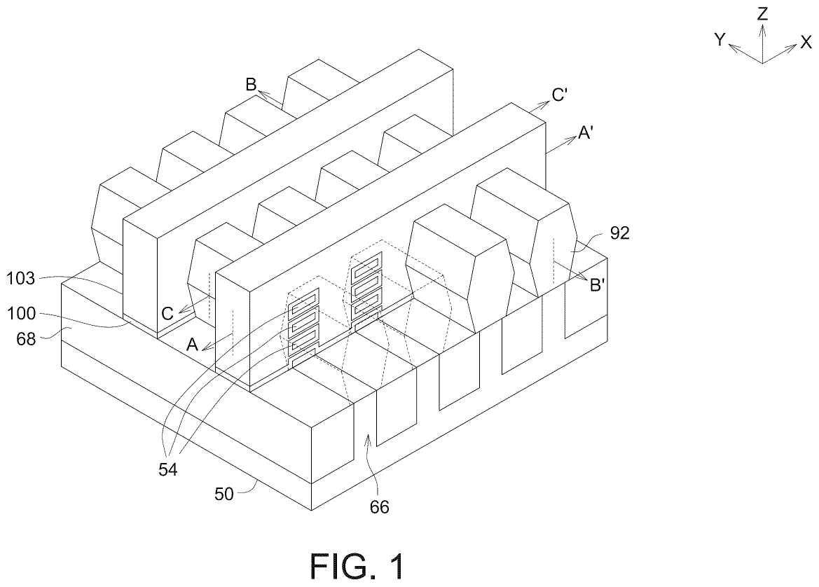

FIG. 1 illustrates an example of nano-FETs (e.g., nanowire FETs, nanosheet FETs, or the like) in a three-dimensional view, in accordance with some embodiments. The nano-FETs comprise nanostructures 54 (e.g., nanosheets, nanowire, or the like) over fins 66 on a substrate 50 (e.g., a semiconductor substrate), wherein the nanostructures 55 act as channel regions for the nano-FETs. The nanostructures 55 may include p-type nanostructures, n-type nanostructures, or a combination thereof. Shallow trench isolation (STI) regions 68 are disposed between adjacent fins 66, which may protrude above and form between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 100 extend along t-op surfaces and side surfaces of the fins 66 and along top surfaces, side surfaces, and bottom surfaces of the nanostructures 55. Gate electrodes 103 are over the gate dielectric layers 100. Epitaxial source/drain regions 92 are disposed on the fins 66 on opposing sides of the gate dielectric layers 101 and the gate electrodes 103.

FIG. 1 further illustrates reference cross-sections that are used in later figures. Cross-section A-A′ is along a longitudinal axis of a gate electrode 103 and in a direction, for example, perpendicular to the direction of current flow between the epitaxial source/drain regions 92 of a nano-FET. Cross-section C-C′ is parallel to cross-section A-A′ and extends through epitaxial source/drain regions 92 of multiple nano-FETs. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

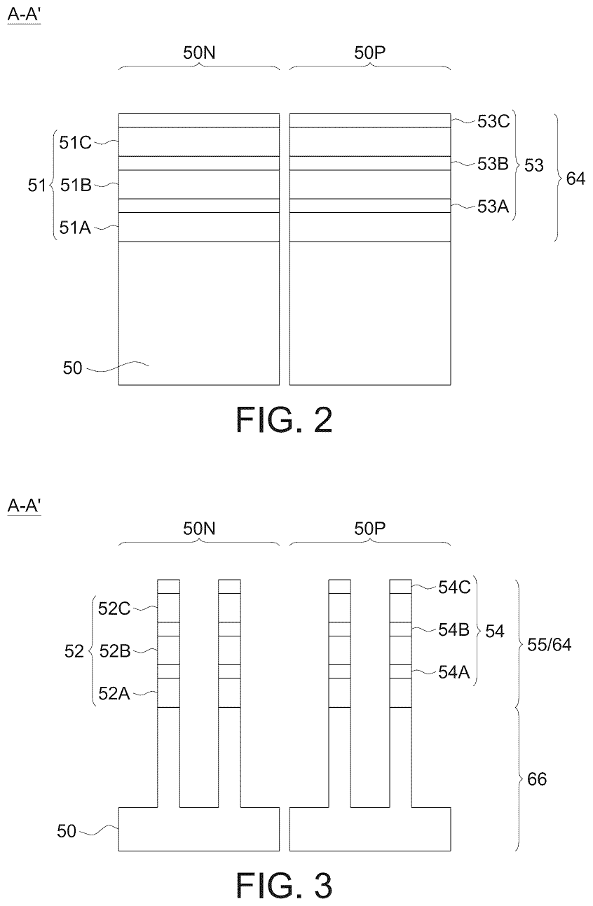

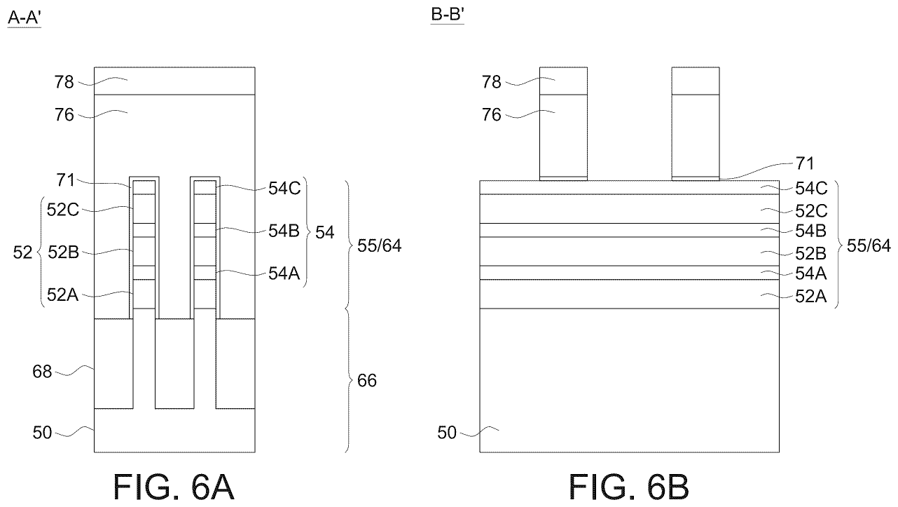

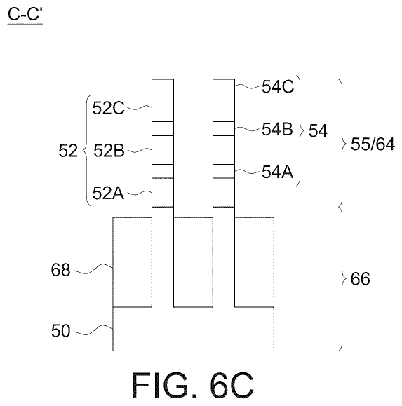

FIGS. 2 through 22 are cross-sectional views of intermediate stages in the manufacturing of nano-FETs, in accordance with some embodiments. FIGS. 2 through 5, 6A, 7A, 8A, 9A, 10A, 11A, 12A, 13, 14, 15, 16, 17, 18, 19, 20A, 20B, 21A, 21B and 22 illustrate reference cross-section A-A′ illustrated in FIG. 1. FIGS. 6B, 7B, 8B, 9B, 10B and 11B, 12B illustrate reference cross-section B-B′ illustrated in FIG. 1. FIGS. 6C, 7C, 8C, 9C, 12C and 12D illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material, such as silicon, silicon carbon, or the like. The multi-layer stack 64 is illustrated as having a bottommost semiconductor layer formed of the first semiconductor materials for illustrative purposes. In some embodiments, the multi-layer stack 64 may be formed such that the bottommost layer is formed of the second semiconductor materials.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), a neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than widths of the fins 66 in the p-type region 50P. Further, while each of the fins 66 and the nanostructures 55 are illustrated as having consistent widths throughout, in other embodiments, the fins 66 and/or the nanostructures 55 may have tapered sidewalls such that widths of the fins 66 and/or the nanostructures 55 continuously increases in a direction towards the substrate 50. In such embodiments, each of the nanostructures 55 may have different widths and be trapezoidal in shape.

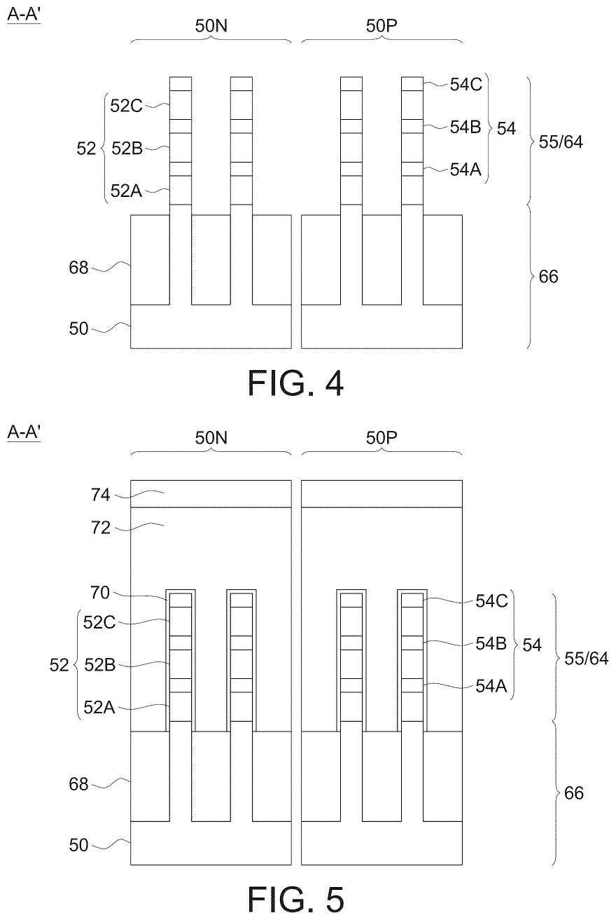

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent ones of the fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along surfaces of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that the nanostructures 55 and upper portions of fins 66 in the n-type region 50N and the p-type region 50P protrude from between neighboring STI regions 68. Further, the top surfaces of the STI regions 68 may have flat surfaces as illustrated, convex surfaces, concave surfaces (such as dishing), or combinations thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid (dHF) may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and the resulting first nanostructures 52) and the second semiconductor layers 53 (and the resulting second nanostructures 54) are illustrated and discussed herein as comprising the same materials in the p-type region 50P and the n-type region 50N for illustrative purposes only. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 26B illustrate various additional steps in the manufacturing of embodiment devices. FIGS. 6A through 26B illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66 and portions of the second nanostructures 54, which form channel regions. The pattern of the masks 78 may be used to separate each of the dummy gates 76 from adjacent dummy gates 76. The dummy gates 76 may have lengthwise directions perpendicular to lengthwise directions of respective ones of the fins 66.

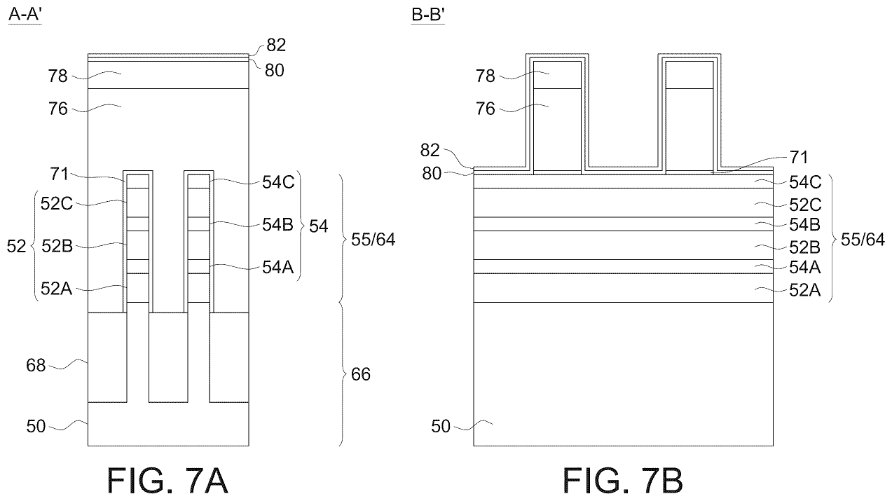

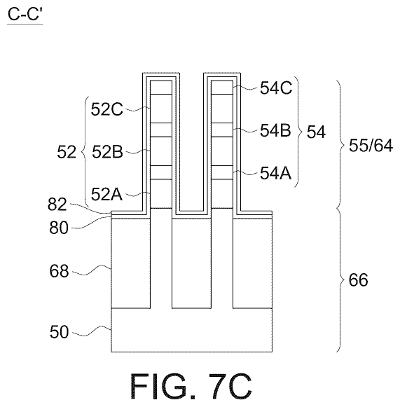

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; side surfaces of the fins 66, the dummy gate dielectrics 71, and the dummy gates 76; and top surfaces and side surfaces of the nanostructures 55 and the masks 78. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like. The first spacer layer 80 and the second spacer layer 82 may comprise low-k dielectric materials.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and the exposed nanostructures 55 in the p-type region 50P. The mask may then be removed. Subsequently, a mask, such as a photoresist, may be formed over the p-type region 50P while exposing the n-type region 50N, and appropriate type (e.g., n-type) impurities may be implanted into the exposed fins 66 and the exposed nanostructures 55 in the n-type region 50N. The mask may then be removed. The n-type impurities may be the any of the n-type impurities previously discussed and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

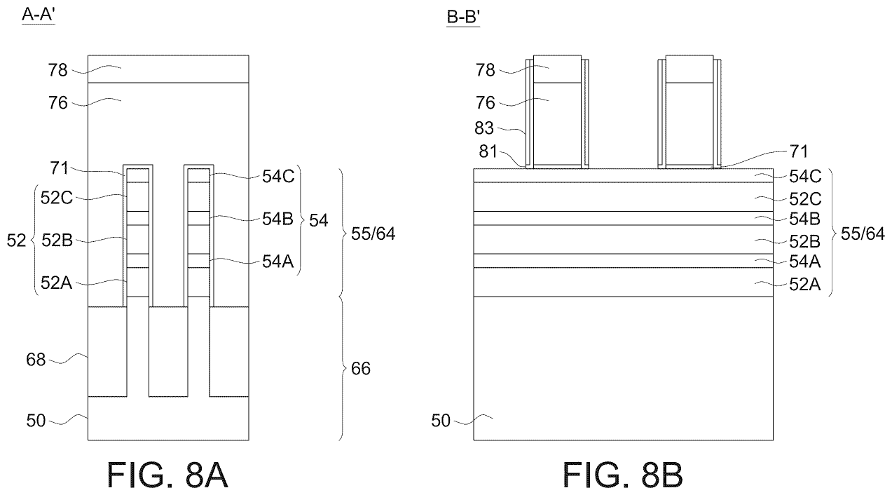

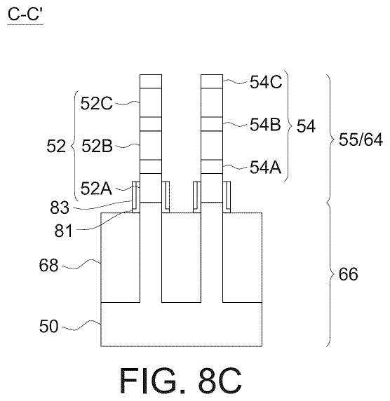

In FIGS. 8A through 8C, the first spacer layer 80 and the second spacer layer 82 are etched to form first spacers 81 and second spacers 83, respectively. As will be discussed in greater detail below, the first spacers 81 and the second spacers 83 act to self-align subsequently formed source/drain regions, as well as to protect sidewalls of the fins 66 and/or the nanostructures 55 during subsequent processing. The first spacer layer 80 and the second spacer layer 82 may be etched using suitable etching processes, such as isotropic etching processes (e.g., wet etching processes), anisotropic etching processes (e.g., dry etching processes), or the like. In some embodiments, the material of the second spacer layer 82 has a different etch rate than the material of the first spacer layer 80, such that the first spacer layer 80 may act as an etch stop layer when patterning the second spacer layer 82. The second spacer layer 82 may act as a mask when patterning the first spacer layer 80. For example, the second spacer layer 82 may be etched using an anisotropic etch process in which the first spacer layer 80 acts as an etch stop layer. Remaining portions of the second spacer layer 82 form the second spacers 83, as illustrated in FIGS. 8B and 8C. The second spacers 83 then act as a mask while etching exposed portions of the first spacer layer 80 forming the first spacers 81, as illustrated in FIGS. 8B and 8C.

As illustrated in FIG. 8B, the first spacers 81 and the second spacers 83 are disposed on sidewalls of the masks 78, the dummy gates 76, and the dummy gate dielectrics 71. In some embodiments, top surfaces of the first spacers 81 and the second spacers 83 may be disposed below top surfaces of the masks 78. The top surfaces of the first spacers 81 and the second spacers 83 may be disposed level with or above the top surfaces of the masks 78. In some embodiments, the second spacers 83 may be removed from over the first spacers 81 adjacent the masks 78, the dummy gates 76, and the dummy gate dielectrics 71. As illustrated in FIG. 8C, the first spacers 81 and the second spacers 83 are disposed on sidewalls of the fins 66 and/or nanostructures 55.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

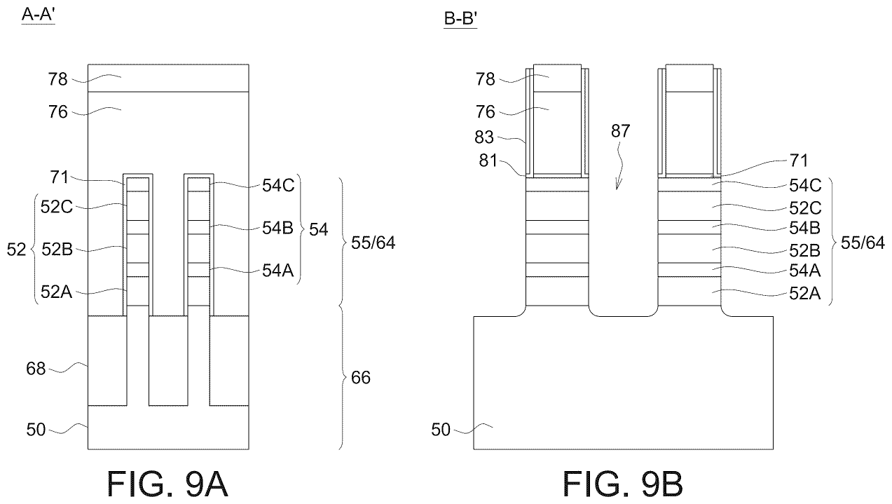

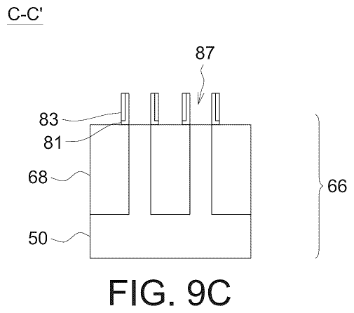

In FIGS. 9A through 9C, first recesses 87 are formed in the fins 66, the nanostructures 55, and the substrate 50. Epitaxial source/drain regions will be subsequently formed in the first recesses 87. The first recesses 87 may extend through the first nanostructures 52 and the second nanostructures 54, and into the substrate 50. In some embodiments, top surfaces of the STI regions 68 may be level with bottom surfaces of the first recesses 87. In some embodiments, the top surfaces of the STI regions 68 may be above or below the bottom surfaces of the first recesses 87. The first recesses 87 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 87. A single etch process or multiple etch processes may be used to etch each layer of the nanostructures 55 and/or the fins 66. Timed etch processes may be used to stop the etching after the first recesses 87 reach desired depths.

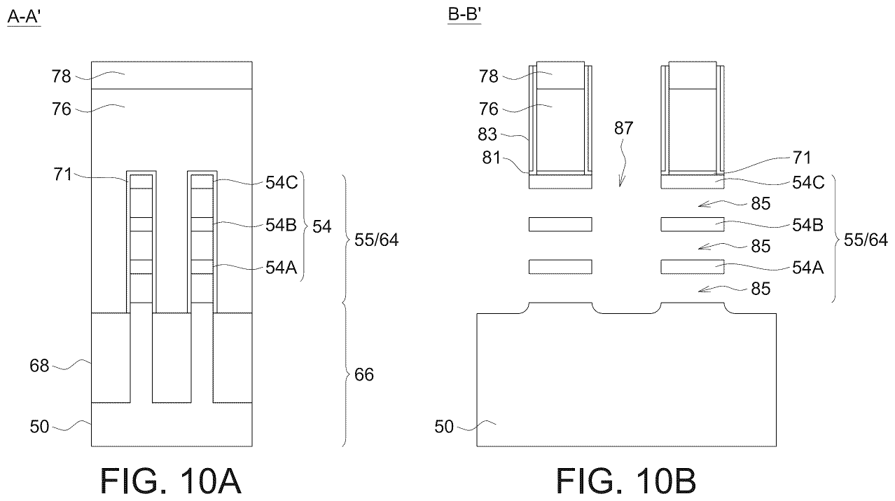

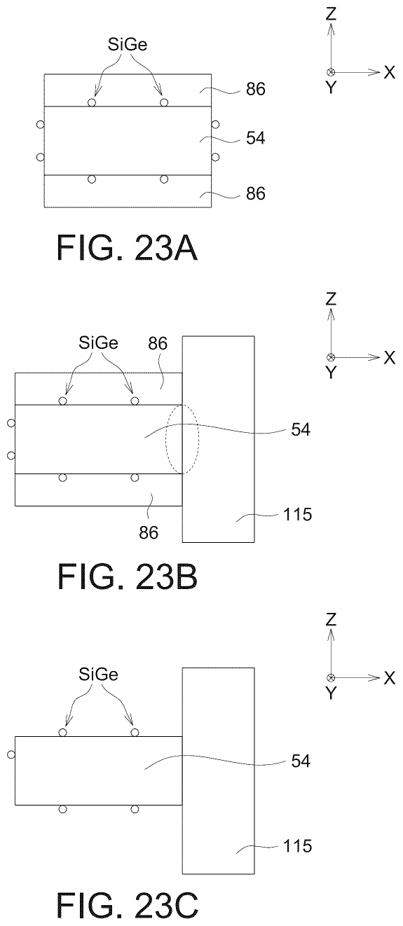

In FIGS. 10A and 10B, each of the first nanostructures 52A-52C of the multi-layer stack 64 is removed to form a plurality of cavities 85. In some embodiments, the first nanostructures 52A-52C are removed through a wet etching process. In the case where the first nanostructures 52A-52C are made of SiGe and the second nanostructures 54A-54C is made of silicon, the first nanostructures 52A-52C can be selectively etched using a wet etchant such as, but not limited to, ammonium hydroxide (NH4OH), tetramethylammonium hydroxide (TMAH), ethylenediamine pyrocatechol (EDP) or potassium hydroxide (KOH) solutions to expose the upper and lower surfaces of the second nanostructures 54A-54C and the upper surface of the substrate 50. The first nanostructures 52A-52C made of SiGe are replaced by the sacrificial dielectric layers 86 so as to reduce SiGe intermixing in the interfacial surfaces of the second nanostructures 54 as shown in FIG. 23A.

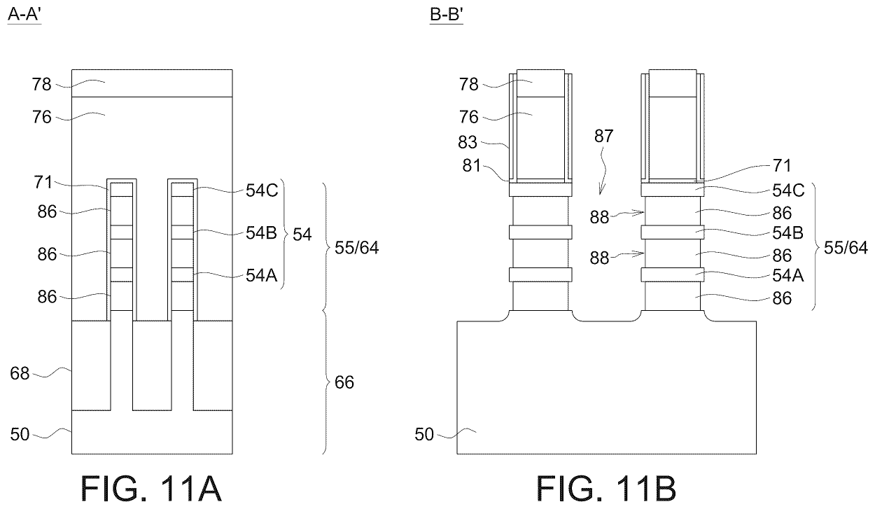

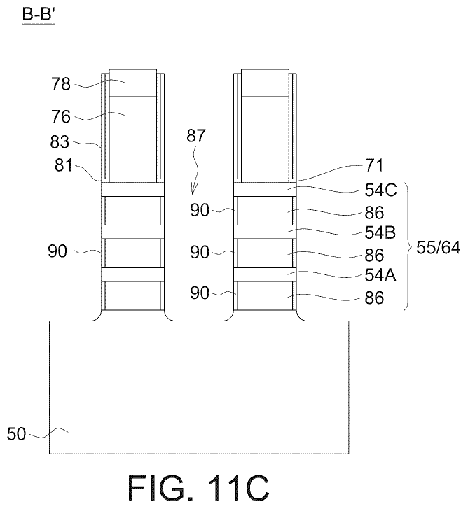

In FIG. 11B, after the first nanostructures 52A-52C are removed, a dielectric material is deposited on the upper and lower surfaces of the second nanostructures 54A-54C and the upper surface of the substrate 50 exposed in the cavities 85 to form a plurality of sacrificial dielectric layers 86. The sacrificial dielectric layers 86 may be made of a low-k dielectric material, such as SiOx. Next, by removing the edge portion of the sacrificial dielectric layers 86 along the Y direction, the side surfaces and a part of the upper and lower surfaces of the second nanostructures 54A-54C are exposed to form a plurality of sidewall recesses 88 between the second nanostructures 54A-54C.

In FIG. 11C, a dielectric layer is deposited in each sidewall recess 88 to form inner spacers 90. In addition to filling the sidewall recesses 88, the inner layers 90 are also deposited in the bottom of the first recesses 87 and the side surfaces of the second nanostructures 54A-54C. In order to avoid excess dielectric layer remaining in the bottom of the first recesses 87, the dielectric layer is partially removed through the etching process, leaving only the inner spacers 90 in the sidewall recesses 88. The etching process may be dry or wet etching such as RIE, NBE or the like. The inner spacers 90 may be made of a low-k dielectric material, such as SiON, SiCN, SiOC, SiOCN, or SiN. In some embodiments, the inner spacers 90 are formed from a material having a dielectric constant in the range of 3.5 to 5.5. The inner spacers 90 may be formed by atomic layer deposition, pulsed plasma chemical vapor deposition, or any suitable deposition process. The end portion of the inner spacers 90 may have a flat surface that is substantially coplanar with the side surfaces of the second nanostructures 54A-54C. Although outer sidewalls of the inner spacers 90 are illustrated as flush with sidewalls of the second nanostructures 54A-54C, the outer sidewalls of the inner spacers 90 may extend beyond or be recessed from sidewalls of the second nanostructures 54A-54C.

The inner spacers 90 act as isolation features between subsequently formed source/drain regions 92 and subsequently formed gate structures. As will be discussed in detail below, the source/drain regions 92 will be formed in the first recesses 87.

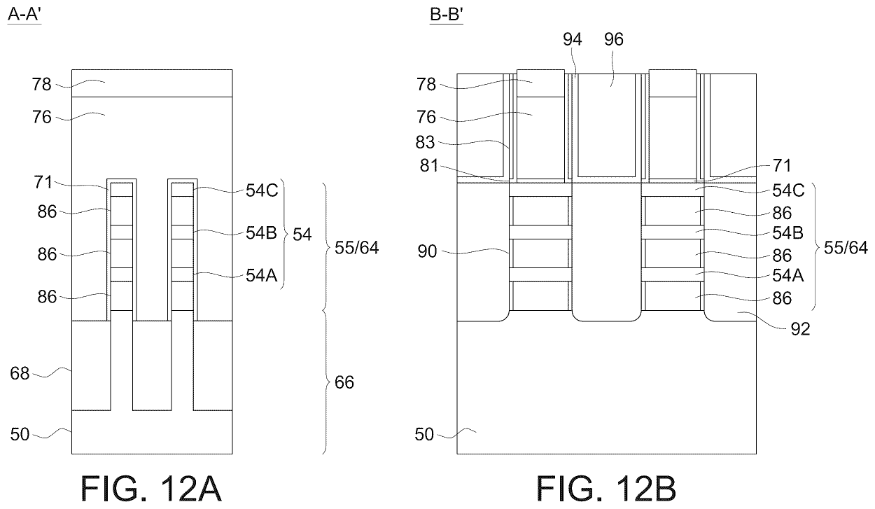

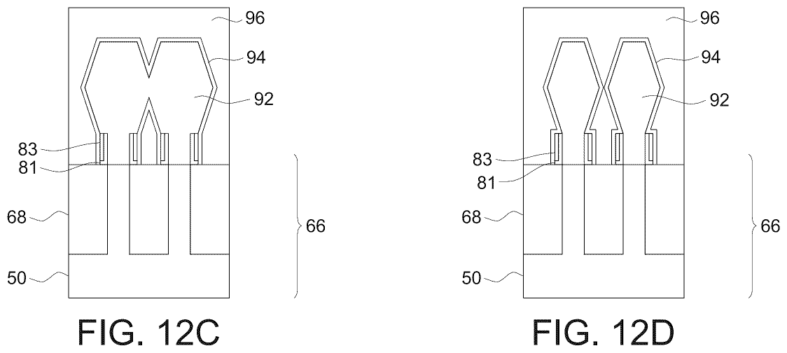

In FIGS. 12A through 12D, epitaxial source/drain regions 92 are formed in the first recesses 87. In some embodiments, the epitaxial source/drain regions 92 may exert stress on the second nanostructures 54, thereby improving performance. As illustrated in FIG. 12B, the epitaxial source/drain regions 92 are formed in the first recesses 87 such that each dummy gate 76 is disposed between respective neighboring pairs of the epitaxial source/drain regions 92. In some embodiments, the first spacers 81 and the second spacers 83 are used to separate the epitaxial source/drain regions 92 from the dummy gates 76 and the inner spacers 90 are used to separate the epitaxial source/drain regions 92 from the subsequently formed gate structures by appropriate lateral distances so that the epitaxial source/drain regions 92 do not short out subsequently formed gates of the resulting nano-FETs.

In FIG. 12B, the epitaxial source/drain regions 92 in the n-type region, e.g., the NMOS region, may be formed by masking the p-type region, e.g., the PMOS region. Then, the epitaxial source/drain regions 92 are epitaxially grown in the recesses 87 of the n-type region. The epitaxial source/drain regions 92 may include any acceptable material appropriate for n-type nano-FETs. For example, if the second nanostructures 54A-54C are silicon, the epitaxial source/drain regions 92 may include materials exerting a tensile strain on the second nanostructures 54A-54C, such as silicon, silicon carbide, phosphorous-doped silicon carbide, silicon phosphide, or the like. The epitaxial source/drain regions 92 may have surfaces raised from respective upper surfaces of the second nanostructures 54A-54C and may have facets.

The epitaxial source/drain regions 92 in the p-type region, e.g., the PMOS region, may be formed by masking the n-type region, e.g., the NMOS region. Then, the epitaxial source/drain regions 92 are epitaxially grown in the recesses 87 of the p-type region. The epitaxial source/drain regions 92 may include any acceptable material appropriate for p-type nano-FETs. For example, if the second nanostructures 54A-54C are silicon, the epitaxial source/drain regions 92 may comprise materials exerting a compressive strain on the second nanostructures 54A-54C, such as silicon-germanium, boron doped silicon-germanium, germanium, germanium tin, or the like. The epitaxial source/drain regions 92 may also have surfaces raised from respective upper surfaces of the second nanostructures 54A-54C and may have facets.

As a result of the epitaxy processes used to form the epitaxial source/drain regions 92 in the n-type region and the p-type region, upper surfaces of the epitaxial source/drain regions 92 have facets which expand laterally outward beyond sidewalls of the nanostructures 55. In some embodiments, the facets cause adjacent epitaxial source/drain regions 92 of a same nano-FET to merge as illustrated by FIG. 12C. In some embodiments, adjacent epitaxial source/drain regions 92 remain separated after the epitaxy process is completed as illustrated by FIG. 12D. In the embodiments illustrated in FIGS. 12C and 12D, the first spacers 81 may be formed over top surfaces of the STI regions 68 and may block the epitaxial growth. In some embodiments, the first spacers 81 may cover portions of sidewalls of the second nanostructures 54 also block the epitaxial growth beyond the uppermost second nanostructures 54C.

The first and second spacers 81 and 83 may have a thickness in a range between about 4 nm and about 7 nm. In some embodiments, the insulating material of the first and second spacers 81 and 83 is a silicon nitride-based material, such as SiN, SiON, SiOCN or SiCN and combinations thereof. In addition, a contact etch stop layer (CESL) 94 and an interlayer dielectric (ILD) layer 96 are formed over the exposed surfaces, such as on the epitaxial source/drain regions 92, the first and second spacers 81 and 83, and the STI region 68. In some embodiments, the CESL 94 has a thickness in a range between about 4 nm and about 7 nm. The CESL 94 may include Si₃N₄, SiON, SiCN or any other suitable material, and may be formed by CVD, PVD, or ALD. The interlayer dielectric (ILD) layer 96 is formed over the CESL 94. The ILD layer 96 protects the epitaxial source/drain regions 92 during the removal of the dummy gates 76.

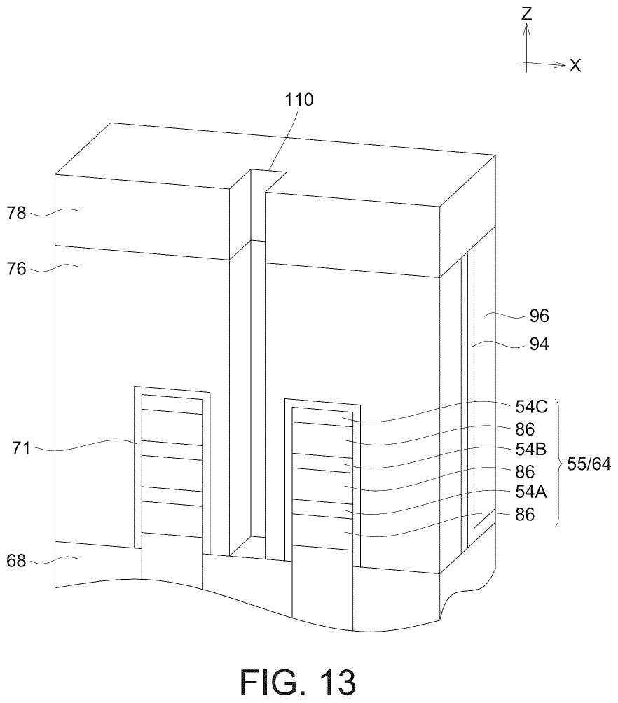

In FIG. 13, the dummy gates 76 and the masks 78 are partially etched to form a recess 110 with high aperture ratio. The recess 110 extends along the vertical direction of the dummy gates 76 and the masks 78 and is formed between two adjacent nanostructures 55, such as between two n-type devices with NMOS transistors, e.g., n-type nano-FETs, or between two p-type devices with PMOS transistors, e.g., p-type nano-FETs.

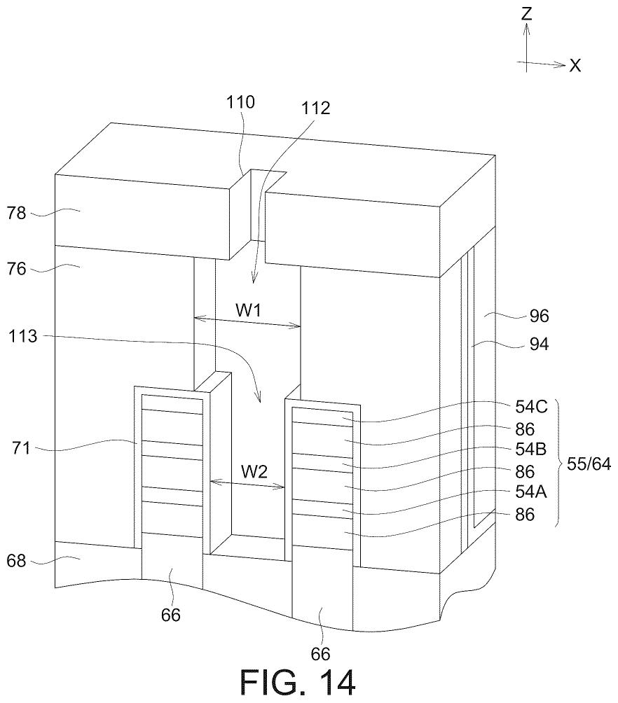

In FIG. 14, the dummy gates 76 are further etched to form a recess 110 with an enlarged opening 112 on the top of the nanostructures 55 and a narrow opening 113 between the nanostructures 55. The enlarged opening 112 has a first width W1 in the lateral direction (i.e. X-cut direction) and the narrow opening 113 on the bottom of the recess 110 has a second width W2 in the same direction. The second width W2 is less than the first width W1 so that a top portion of the dummy gate dielectrics 71 on the top of the nanostructures 55 is exposed from the enlarged opening 112. In addition, side portions of the dummy gate dielectrics 71 on opposite sides of the nanostructures 55 is exposed from the narrow opening 113. In some embodiments, the first width W1 may be between 35 nm and 55 nm, and the first width W2 may be between 35 nm and 50 nm. The width of two adjacent fins 66 may be between 30 nm and 45 nm.

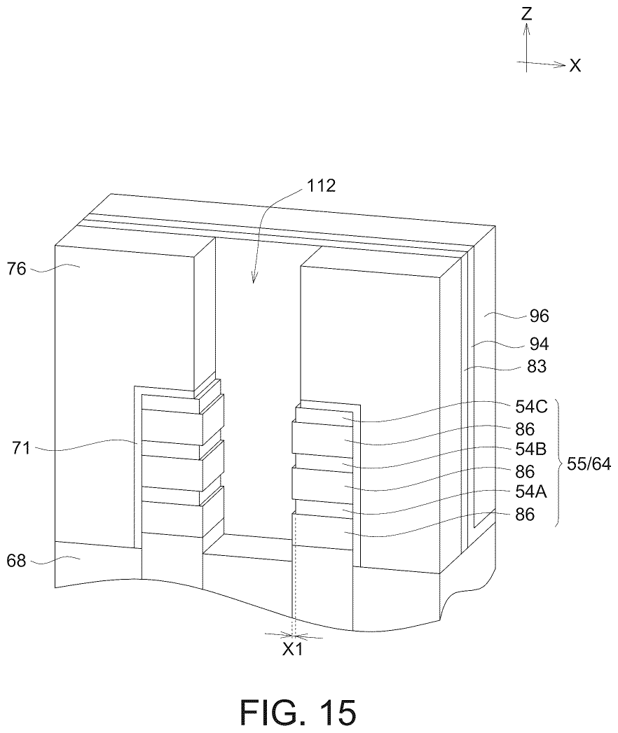

In FIG. 15, the masks 78 are removed and the portions of the dummy gate dielectrics 71 exposed from the enlarged opening 112 and the narrow opening 113 are removed by etching process. Remaining un-etched portions of the dummy gate dielectrics 71 are covered by the dummy gates 76. In addition, silicon trimming operation is then performed on the second nanostructures 54A-54C after the exposed portions of the dummy gate dielectrics 71 are removed so as to reduce SiGe intermixing in the interfacial surfaces of the second nanostructures 54 as shown in FIG. 23B, that is, compared to SiGe intermixing in FIG. 23A, SiGe intermixing is reduced in dotted circle near the dielectric sidewall 115. The silicon trimming refers to etching end surfaces of the second nanostructures 54A-54C in the direction along X-axis so that the second nanostructures 54A-54C are trimmed and shorten by a distance X1, such as in a range between 0 nm and 0.5 nm.

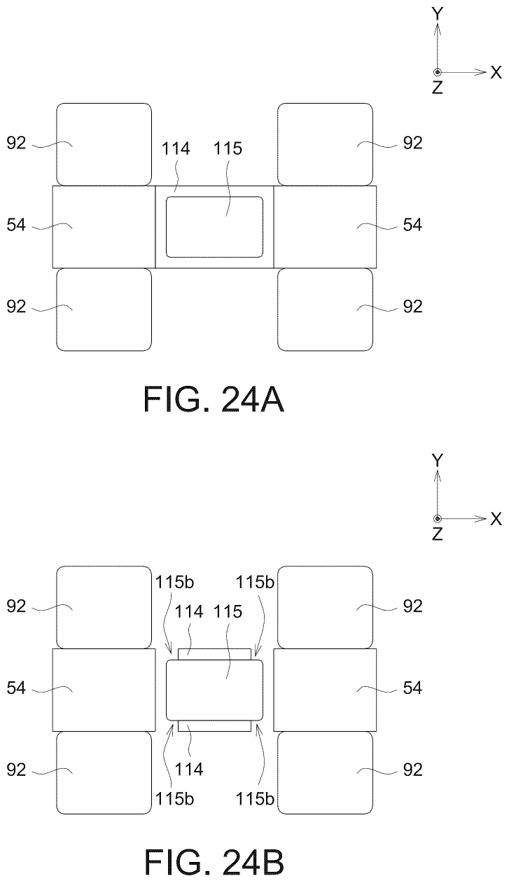

In FIG. 16, a liner 114 is formed in the recess 110. The liner 114 is deposited on the sidewalls and the bottom surface of the recess 110. That is, the liner 114 covers the exposed portions of the nanostructures 55 and the dummy gates 76. In FIG. 16, a dielectric wall 115 is formed in the recess 110 after the liner 114 is formed. The dielectric wall 115 has an enlarged wall 116 corresponding to the enlarged opening 112 of the recess 110 and a narrow wall 117 corresponding to the narrow opening 113 of the recess 110. The width W3 of the enlarged wall 116 is greater than the width W4 of the narrow wall 117. The dielectric wall 115 is formed for separating the two adjacent nanostructures 55 from each other so that the parasitic capacitance induced by EPI/metal gate structure between the nanostructures 55 can be reduced. In some embodiments, the thickness of the liner 114 may be between 1 nm and 2 nm, the width W3 may be between 35 nm and 55 nm, and the width W4 may be between 35 nm and 50 nm. The width of two adjacent fins 66 may be between 30 nm and 45 nm. In FIG. 24A, the liner 114 is formed around the dielectric wall 115 from a top view.

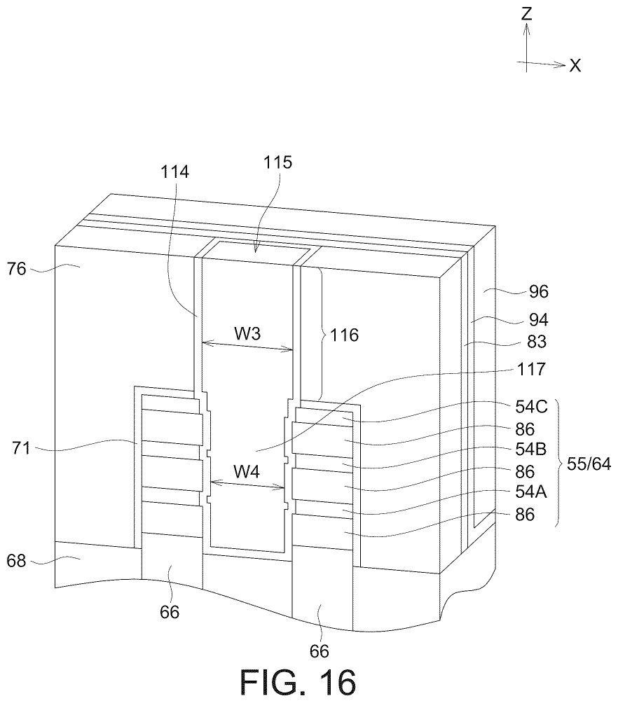

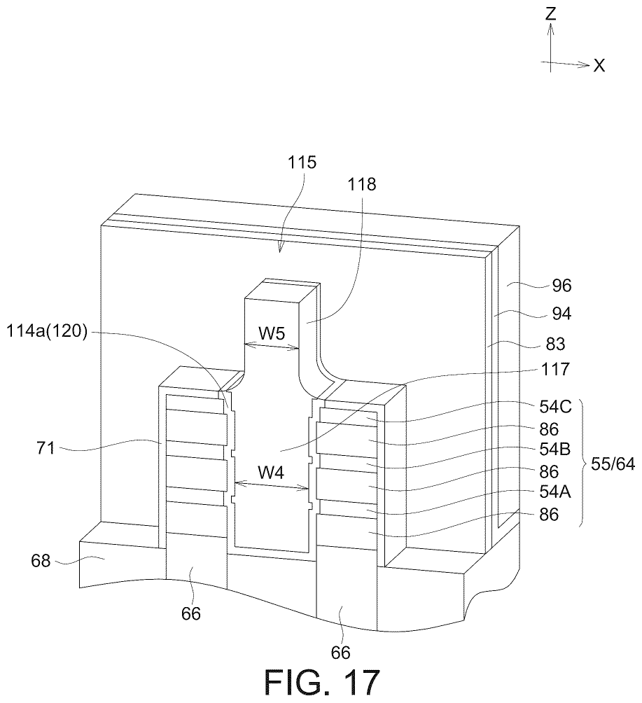

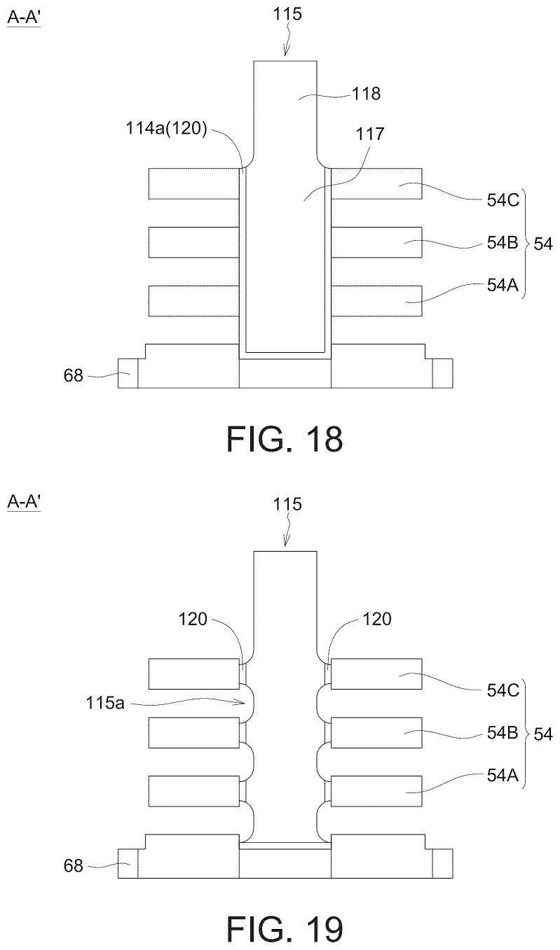

In FIG. 17, the dummy gates 76 are removed in one or more etching steps. Portions of the liner 114 and the dielectric wall 115 are also be removed. In some embodiments, the dummy gates 76 and the liner 114 are removed by an anisotropic dry etch process. For example, the etching process may include a dry etch process using reaction gas(es) that selectively etch the dummy gates 76 at a faster rate than the first spacers 81, the second spacers 83, the nanostructures 55, or the STI regions 68. During the removal of the dummy gates 76 and the liner 114, the dummy gate dielectrics 71 may be used as etch stop layers when the dummy gates 76 are etched. Portions of liner 114 may then be removed after the removal of the dummy gates 76, while the un-etched liner 114a may remain to form one end cap in FIG. 18.

In FIG. 17, the enlarged wall 116 of the dielectric wall 115 may be trimmed by etching process to form a top trimmed portion 118 with a width W5 less than or equal to a width W4 of the lower portion of the dielectric wall 115 (i.e., the narrow wall 117). That is, the top trimmed portion 118 is thinner than the lower portion so that the un-etched liner 114a disposed between the narrow wall 117 and the nanostructures 55 is exposed from the dielectric wall 115. As shown in FIG. 18, after the dummy gate dielectrics 71 are removed, the sacrificial dielectric layers 86 are removed to expose the top surfaces and bottom surfaces of the second nanostructures 54. In some embodiment, the width W5 may be between 30 nm and 40 nm, and the width W4 may be between 35 nm and 50 nm. The width of two adjacent fins 66 may be between 30 nm and 45 nm.

In FIG. 18, the sacrificial dielectric layers 86 may be removed by performing an isotropic etching process such as wet etching or the like using etchants selective to the materials of the sacrificial dielectric layer 86, while the second nanostructures 54, the substrate 50, and the STI regions 68 remain relatively un-etched as compared to the sacrificial dielectric layers 86. In FIG. 23C, after the sacrificial dielectric layers 86 are removed, less SiGe intermixing exists in the interfacial surfaces of the second nanostructures 54.

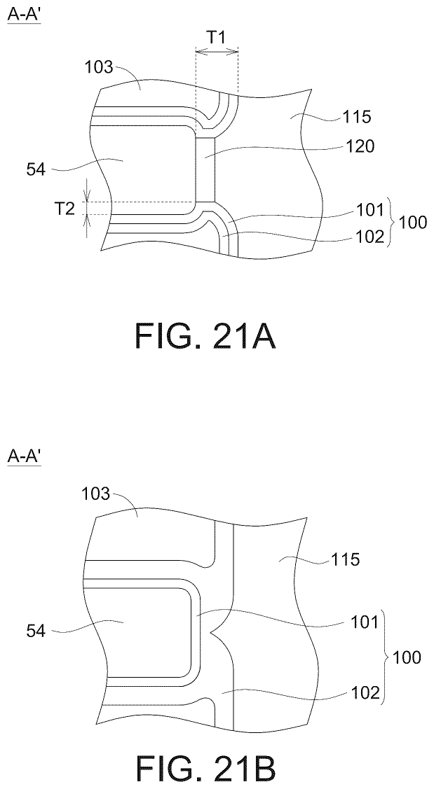

In FIG. 19, when the sacrificial dielectric layers 86 are removed, the un-etched liner 114a may be partially removed to form a plurality of end caps 120 between the second nanostructures 54 and the dielectric wall 115. In addition, the sidewalls of the dielectric wall 115 may be partially removed to form a plurality of concave portions 115a between adjacent two end caps 120. In some embodiments, the end caps 120 may be a SiOx layer, and the dielectric wall 115 may be SiN, SiCN or SiCON. In some embodiments, the end caps 120 may be used to define a gate end cap on a channel of a forksheet structure 60. For example, in FIG. 21A, a thickness T1 of the end caps 120 on an end surface of the second nanostructures 54 may be used to define a thickness of the π-gate (pi-gate) structure. In some embodiments, the thickness T1 of the π-gate structure may be in a range between about 3 nm and about 6 nm, the height T2 of the π-gate structure may be in a range between about 0 nm and about 1 nm, as shown in FIG. 21A.

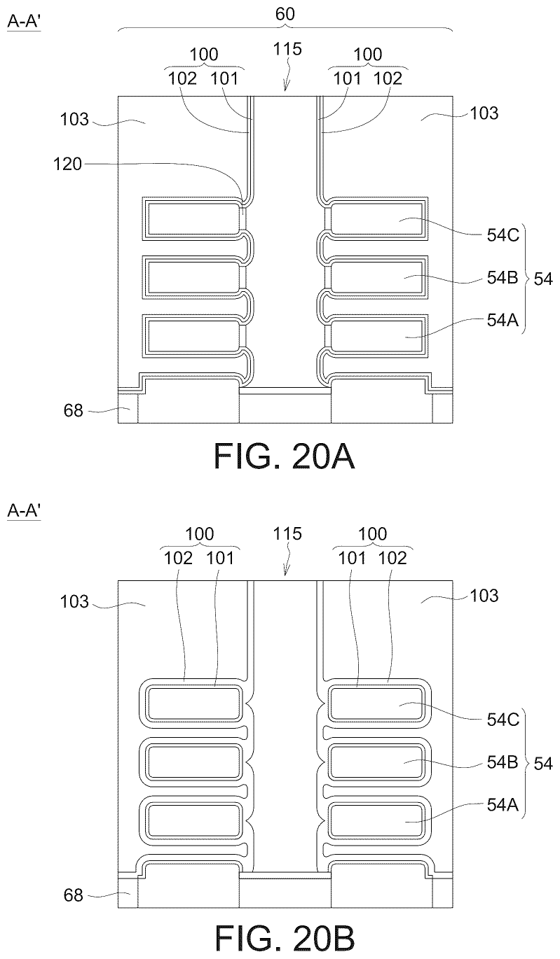

In FIGS. 20B and 21B, when the end caps 120 are fully etched and the sidewalls of the dielectric wall 115 have a taper shape, there will be a large gap for filling gate dielectric layers 100, which could be a surrounding structure instead of π-gate structure for the second nanostructures 54. In FIG. 20B, the second gate dielectric layer 102 of high-k dielectric material may merge at the gap. The second gate dielectric layer 102 has a width about 3-5 nm between the second nanostructures 54 and the dielectric wall 115. In some embodiments, when more of the height of the end caps 120 is removed, the effective length of the subsequent gate structure increases, leading to improved gate control performance. In FIG. 24B, when the liner 114 made of SiOx with faster etching rate than nitride like material is etched, the portions of the liner 114 extending along the Y-cut direction is fully removed due to enough space (for example, greater than 2 nm) between the second nanostructures 54 and the dielectric wall 115, while the remaining liner 114 along the X-cut direction is un-etched to cover middle portions of the dielectric wall 115 from a top view. The edge portions 115b of the dielectric wall 115 on opposite surfaces may be exposed from the liner 114 so that the second gate dielectric layer 102 of high-k dielectric material can insert into the enough space and merge.

In FIG. 20A and FIG. 21A, gate dielectric layers 100 are deposited conformally in the spaces between the second nanostructures 54. The gate dielectric layers 100 may be formed on top surfaces and side surfaces of the fins 66 and on top surfaces, side surfaces, and bottom surfaces of the second nanostructures 54. The gate dielectric layers 100 may also be deposited on top surfaces of the second spacers 83, and the STI regions 68; on top surfaces and side surfaces of the first spacers 81; and on side surfaces of the inner spacers 90 (shown in FIG. 11C). The gate dielectric layers 100 comprise one or more dielectric layers, such as an oxide, a metal oxide, the like, or combinations thereof. In some embodiments, the gate dielectric layers 100 may comprise first gate dielectric layers 101 (e.g., comprising silicon oxide or the like) and second gate dielectric layers 102 (e.g., comprising a metal oxide or the like) of high-k dielectric material. In some embodiments, the second gate dielectric layers 102 may have a k-value greater than about 7.0, and may include a metal oxide or a silicate of hafnium, aluminum, zirconium, lanthanum, manganese, barium, titanium, lead, and combinations thereof. The first gate dielectric layers 101 may be referred to as interfacial layers, and the second gate dielectric layers 102 may be referred to as high-k gate dielectric layers, in some embodiments.

The structure of the gate dielectric layers 100 may be the same or different in the n-type region 50N and the p-type region 50P. For example, the p-type region 50P may be masked or exposed while forming the gate dielectric layers 100 in the n-type region 50N. In embodiments where the p-type region 50P is exposed, the gate dielectric layers 100 may be simultaneously formed in the p-type regions 50P. The formation methods of the gate dielectric layers 100 may include molecular-beam deposition (MBD), ALD, CVD, PVD, and the like.

In FIGS. 20A and 21A, conductive materials 103 formed over the gate dielectric layers 100. The conductive materials 103 are separated by the dielectric structure (i.e., dielectric wall 115). In some embodiments, the conductive materials 103 may be gate electrodes having a π-shape in a cross-sectional view along the lateral direction (i.e., X-axis direction). The dielectric wall 115 is disposed between two adjacent channel regions (i.e., second nanostructures 54) of a forksheet structure 60.

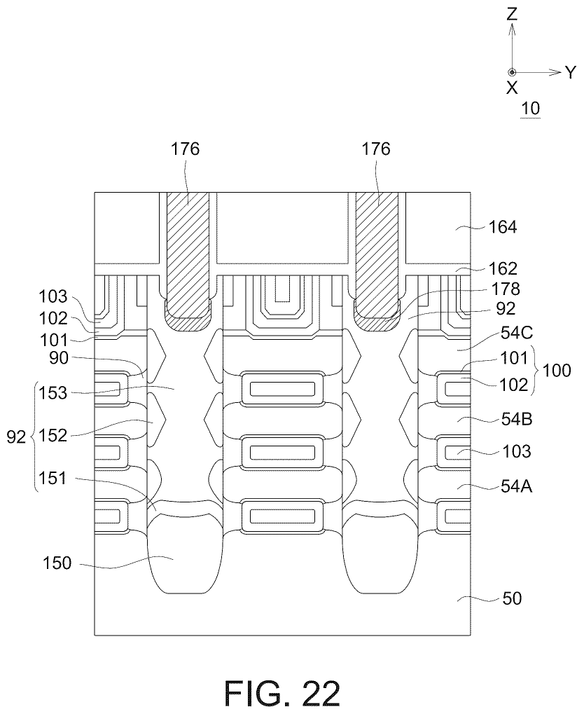

The conductive materials 103 may fill the spaces between the second nanostructures 54 and extend over the gate dielectric layers 100. The conductive materials 103 may be deposited conformally by a process such as ALD, CVD, PVD, or the like. In some embodiments, the conductive materials 103 are a p-type work function layer and/or a n-type work function layer respectively, which may comprise W, Cu, TiN, Ti, Pt, Ta, TaN, Co, Ni, TaC, TaCN, TaSiN, TaSi₂, NiSi₂, Mn, Zr, ZrSi₂, TaN, Ru, Mo, MoSi₂, WN, WCN, other metal oxides, metal nitrides, metal silicates, transition metal-oxides, transition metal-nitrides, transition metal-silicates, oxynitrides of metals, metal aluminates, zirconium silicate, zirconium aluminate, combination thereof, or the like. After filling of the conductive materials 103 over the second nanostructures 54, a planarization process, such as a CMP, may be performed to remove the excess portions of the conductive materials 103, which excess portions are over the top surface of the ILD layer 96, the first spacers 81, and the second spacers 83. In FIG. 22, a planarization process is performed to remove excess portions of the conductive materials 103, and the height of the gate structure from top sheet of the second nanostructures 54 is in a range from 13 nm to 15 nm.

In FIG. 22, source/drain contacts 176 are formed in the second interlayer dielectric layer (IDL) 164. Prior to forming the source/drain contacts 176, contact openings are formed in the second IDL 164 to expose the epitaxial source/drain regions 92. The contact openings are formed through various layers, including second interlayer dielectric layer 164 and contact etch stop layer 162, using suitable photolithography and etching techniques to expose epitaxial source/drain regions 92. In some embodiments, upper portions of the epitaxial source/drain regions 92 are etched.

The epitaxial source/drain regions 92 may comprise one or more semiconductor material layers. For example, the epitaxial source/drain regions 92 may comprise a first semiconductor material 151, a second semiconductor material 152, and a third semiconductor material 153. Any number of semiconductor material may be used for the epitaxial source/drain regions 92. Each of the first semiconductor material 151, the second semiconductor material 152, and the third semiconductor material 153 may be formed of different semiconductor materials and may be doped to different dopant concentrations. In some embodiments, the first semiconductor material 151 may have a dopant concentration less than the second semiconductor material 152 and greater than the third semiconductor material 153. In embodiments in which the epitaxial source/drain regions 92 comprise three semiconductor material, the first semiconductor material 151 may be deposited on the separation layer 150 at the bottom of the source/drain regions 92, the second semiconductor material 152 may be deposited on the second nanostructures 54A-54C and the inner spacers 90, and the third semiconductor material 153 may be deposited over the first and second semiconductor materials 151 and 152.

After forming the contact openings, a silicide layer 178 is formed over the epitaxial source/drain regions 92. The silicide layer 178 electrically couples the epitaxial source/drain regions 92 to subsequently formed source/drain contacts 176. The silicide layer 178 may be formed by depositing a metal source layer over epitaxial source/drain regions 92 and performing a rapid thermal annealing process. During the rapid anneal process, a portion of the metal source layer over the epitaxial source/drain regions 92 reacts with the silicon in the epitaxial source/drain regions 92 to form a silicide layer 178. Next, the unreacted portion of the metal source layer is removed. In some embodiments, silicide layer 178 is made of metal or metal alloy silicide, and the metal includes noble metals, refractory metals, rare earth metals, alloys thereof, or combinations thereof. Next, conductive material is formed in the contact openings to form the source/drain contacts 176. The conductive material may be made of materials including one or more of Ru, Mo, Co, Ni, W, Ti, Ta, Cu, Al, TiN, and TaN. Although not shown, prior to forming the source/drain contacts 176, a barrier layer (e.g., TiN, TaN, or the like) may be formed on the sidewalls of the contact openings. Next, a planarization process such as chemical mechanical polishing is performed to remove excess deposited contact material and expose the top surface of the source/drain contacts 176.

It should be understood that the semiconductor device 10 may undergo further complementary metal oxide semiconductor (CMOS) processes and/or back-end-of-line (BEOL) processes to form various features, such as transistors, contacts/vias, interconnect metal layers, dielectric layers, passivation layers, etc. The semiconductor device 10 may also include backside source/drain contacts on the backside of the substrate 50 such that the sources or drains of epitaxial source/drain regions 92 are connected to the backside power rail (for example, positive voltage VDD or negative voltage VSS) via the backside source/drain contacts.

Referring to FIG. 23A to FIG. 23C, an example of intermediate stages in the manufacturing of nano-FET from Source/Drain loop, Super-Cut-Sheet (SCS) loop to Replace-Poly-Gate (RPG) loop is illustrated, respectively. In FIG. 23A, the first nanostructures 52 are replaced by the sacrificial dielectric layer 86 so that less SiGe intermixing in the interfacial surfaces of the second nanostructures 54 can be achieved. In FIG. 23B, a dielectric wall 115 is formed on one side of the second nanostructures 54 for separating forksheet nanostructures from each other so that the parasitic capacitance induced by epitaxial/metal gate structure between the nanostructures can be reduced. In FIG. 23C, when the sacrificial dielectric layer 86 is removed, the gate dielectric layers 100 may be formed on top surfaces, side surfaces, and bottom surfaces of the second nanostructures 54 or all around the surfaces of the second nanostructures 54.

The present disclosure is directed to improving the performance of the nano-FET. The dielectric structure is formed for separating two adjacent nanostructures from each other so that the parasitic capacitance induced by epitaxial/metal gate structure between the nanostructures can be reduced. In some embodiments, the present disclosure is directed to improving interface state trap density (i.e., Dᵢₜ) by replacing SiGe nanostructures with sacrificial dielectric layer (e.g., oxide layer) during the source/drain loop, so that the SiGe intermixing concern in the Si nanostructures can be reduced. Less SiGe intermixing and reduction of parasitic capacitances between the nanostructure channels can be achieved when the SiGe nanostructures are replaced by oxide layer. In addition, with additional silicon cap trimming and using oxide as the end cap of the dielectric wall, short-channel effect of nano-FETs, such as Drain-induced barrier lowering (DIBL), is improved.

According to some embodiments, the present disclosure provides a semiconductor device comprising a first channel region (i.e., nanostructures 54), a second channel region (i.e., nanostructures 54), a dielectric structure and a first gate structure. The first channel region extends over a semiconductor substrate 50. The second channel region extends over the semiconductor substrate and is parallel to the first channel region in a first direction (i.e. Y-cut direction). The dielectric structure is disposed between the first and second channel regions, wherein the dielectric structure comprises a dielectric wall 115 having a first surface facing the first channel region, a second surface facing the second channel region, a third surface connecting the first and second surfaces, and a fourth surface opposing the third surface. The first gate structure covers the first channel region in a second direction perpendicular to the first direction, and the first gate structure is disposed at one side of the dielectric wall, wherein the first gate structure is in contact with the first surface and edge portions of the third and fourth surfaces.

According to some embodiments, the present disclosure provides a semiconductor device comprising a first channel region (i.e., nanostructures 55), a second channel region (i.e., nanostructures 55) and a dielectric structure. The first channel region extends over a semiconductor substrate 50. The second channel region extends over the semiconductor substrate and is parallel to the first channel region in a first direction (i.e. Y-cut direction). The dielectric structure is disposed between the first and second channel regions, wherein the dielectric structure comprises a dielectric wall and a liner, the dielectric wall has a first surface facing the first channel region, a second surface facing the second channel region, a third surface connecting the first and second surfaces, and a fourth surface opposing the third surface. The liner is disposed over middle portions of the third and fourth surfaces of the dielectric wall. The dielectric wall has a top trimmed wall and a lower portion, and a width of the top trimmed wall is less than or equal to a width of the lower portion in a second direction perpendicular to the first direction.

According to some embodiments, the present disclosure provides a method for manufacturing a semiconductor device as follows. A first channel region (i.e., nanostructures 54A-54C) and a first sacrificial dielectric layer 86 stacked on the first channel region are formed. A second channel region (i.e., nanostructures 54A-54C) and a second sacrificial dielectric layer 86 stacked on the second channel region are formed, the second channel region is adjacent to the first channel region, and the second channel region is parallel to the first channel region in a first direction (i.e. Y-cut direction). End surfaces of the first and second channel regions in a second direction perpendicular to the first direction are etched. A dielectric structure is formed between the first and second channel regions, wherein the dielectric structure comprises a dielectric wall 115 and a liner 114, the dielectric wall 115 has a first surface facing the first channel region, a second surface facing the second channel region, a third surface connecting the first and second surfaces, and a fourth surface opposing the third surface. The liner is disposed over middle portions of the third and fourth surfaces of the dielectric wall. The first sacrificial dielectric layer 86 and the second sacrificial dielectric layer 86 are removed to expose two opposing sides of the dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first channel region extending over a semiconductor substrate;
a second channel region extending over the semiconductor substrate and parallel to the first channel region in a first direction;
a dielectric structure disposed between the first and second channel regions, wherein the dielectric structure comprises a dielectric wall having a first surface facing the first channel region, a second surface facing the second channel region, a third surface connecting the first and second surfaces, and a fourth surface opposing the third surface; and
a first gate structure covering the first channel region in a second direction perpendicular to the first direction, and the first gate structure is disposed at one side of the dielectric wall, wherein the first gate structure is in contact with the first surface and edge portions of the third and fourth surfaces.

2. The semiconductor device according to claim 1, wherein the dielectric wall comprises one or more low-k dielectric material.

3. The semiconductor device according to claim 1, wherein the dielectric structure further comprises a liner, and the liner is disposed over middle portions of the third and fourth surfaces of the dielectric wall.

4. The semiconductor device according to claim 3, wherein a material of the liner includes silicon oxide.

5. The semiconductor device according to claim 1, wherein the first gate structure comprises a first gate dielectric layer disposed on the first channel region and a first gate electrode layer disposed on the first gate dielectric layer, wherein the first gate dielectric layer is in contact with the first surface and the edge portions of the third and fourth surfaces of the dielectric wall.

6. The semiconductor device according to claim 1, further comprising a second gate structure covering the second channel region in the second direction, and the second gate structure being disposed at another side of the dielectric wall, wherein the second gate structure is in contact with the second surface and another edge portions of the third and fourth surfaces, and the first and second gate structures are separated by the dielectric wall.

7. The semiconductor device according to claim 6, wherein the second gate structure comprises a second gate dielectric layer disposed on the second channel region and a second gate electrode layer disposed on the second gate dielectric layer, wherein the second gate dielectric layer is in contact with the second surface and the another edge portions of the third and fourth surfaces of the dielectric wall.

8. The semiconductor device according to claim 6, wherein the dielectric structure further comprises first end caps and second end caps disposed on first and second surfaces of the dielectric wall and connected to the first channel region and the second channel region, respectively.

9. The semiconductor device according to claim 8, wherein the first and second gate structures have a π-shape in a cross-sectional view along the second direction.

10. A semiconductor device comprising:
a first channel region extending over a semiconductor substrate;
a second channel region extending over the semiconductor substrate and parallel to the first channel region in a first direction; and
a dielectric structure disposed between the first and second channel regions, wherein the dielectric structure comprises a dielectric wall, the dielectric wall has a first surface facing the first channel region, a second surface facing the second channel region, a third surface connecting the first and second surfaces, and a fourth surface opposing the third surface,
wherein the dielectric wall has a top portion and a lower portion, and a width of the top portion is less than or equal to a width of the lower portion in a second direction perpendicular to the first direction.

11. The semiconductor device according to claim 10, further comprising a first gate structure covering the first channel region in the second direction, and the first gate structure being disposed at one side of the dielectric wall, wherein the first gate structure is in contact with the first surface and edge portions of the third and fourth surfaces.

12. The semiconductor device according to claim 11, further comprising a second gate structure covering the second channel region in the second direction, and the second gate structure being disposed at another side of the dielectric wall, wherein the second gate structure is in contact with the second surface and another edge portions of the third and fourth surfaces, and the first and second gate structures are separated by the dielectric wall.

13. The semiconductor device according to claim 12, wherein the dielectric structure further comprises first end caps and second end caps disposed on first and second surfaces of the dielectric wall and connected to the first channel region and the second channel region, respectively.

14. The semiconductor device according to claim 13, wherein each of the first and second gate structures has a π-shape in a cross-sectional view along the second direction.

15. A method for manufacturing a semiconductor device comprising:
forming a first channel region and a first sacrificial dielectric layer stacked on the first channel region;
forming a second channel region and a second sacrificial dielectric layer stacked on the second channel region, wherein the second channel is adjacent to the first channel region, and the second channel region is parallel to the first channel region in a first direction;
etching end surfaces of the first and second channel regions in a second direction perpendicular to the first direction;
forming a dielectric structure between the first and second channel regions; and
removing the first sacrificial dielectric layer and the second sacrificial dielectric layer to expose two opposing sides of the dielectric structure.

16. The method according to claim 15, wherein forming the dielectric structure comprises:
depositing a dummy dielectric layer on the first and second channel regions;
depositing a dummy gate layer over the dummy dielectric layer;
forming a mask layer over the dummy gate layer;
partially etching the dummy gate layer and the mask layer to form a recess, wherein the recess has an enlarged opening on an upper portion of the recess and a narrow opening on a lower portion of the recess;
etching the dummy dielectric layer in the recess to expose a plurality of first and second nanostructures of the first and second channel regions on opposite sides of the recess;
forming the liner in the recess to cover the sidewalls of the first and second nanostructures; and
forming the dielectric wall over the liner, wherein the liner separates the first and second nanostructures from the dielectric wall, wherein the dielectric structure comprises a dielectric wall and a liner, the dielectric wall has a first surface facing the first channel region, a second surface facing the second channel region, a third surface connecting the first and second surfaces, and a fourth surface opposing the third surface,
wherein the liner is disposed over middle portions of the third and fourth surfaces of the dielectric wall.

17. The method according to claim 16, wherein forming the dielectric structure further comprises:
removing the dummy gate layer and a portion of the liner deposited on a top enlarged portion of the dielectric wall, wherein the top enlarged portion is corresponding to the enlarged opening; and
etching the top enlarged portion of the dielectric wall to form a top trimmed portion, wherein a width of the top trimmed portion is less than or equal to a lower portion of the dielectric wall.

18. The method according to claim 17, wherein forming the dielectric structure further comprises:
removing the dummy dielectric layer and a portion of the liner deposited on the lower portion of the dielectric wall, and remaining un-etched portions of the liner to form first and second end caps, wherein the first and second end caps are disposed on opposite sides of the dielectric wall and connected to the first channel region and the second channel region, respectively.

19. The method according to claim 18, further comprising:
forming a first gate structure to cover the first channel region in the second direction, and the first gate structure is disposed at one side of the dielectric wall ; and
forming a second gate structure to cover the second channel region in the second direction, and the second gate structure is disposed at another side of the dielectric wall, wherein the first and second gate structures are separated by the dielectric wall,
wherein the first gate structure is in contact with the first surface and edge portions of the third and fourth surfaces, and the second gate structure is in contact with the second surface and another edge portions of the third and fourth surfaces.

20. The method according to claim 19, wherein each of the first and second gate structures has a π-shape in a cross-sectional view along the second direction.
